(19) United States
(12) Patent Application Publication
(10) Pub. No.: US 2025/0056913 A1
(43) Pub. Date: Feb. 13, 2025

(54) SENSOR DEVICE

(71) Applicant: SONY SEMICONDUCTOR SOLUTIONS CORPORATION, KANAGAWA (JP)

(72) Inventor: SAYAKA TAKAI, KANAGAWA (JP)

(21) Appl. No.: 18/718,096

(22) PCT Filed: Dec. 17, 2021
(86) PCT No.: PCT/JP2021/046768

§ 371 Date: Jun. 10, 2024

(51) Int. Cl. H01L 27/146; G01J 1/44; G01S 17/08; H04N 25/10; H04N 25/20

(52) U.S. Cl. CPC H01L 27/14625; G01J 1/44; G01S 17/08; H01L 27/14645; H01L 27/14649; H04N 25/10; H04N 25/20; G01J 2001/448

(57) ABSTRACT

A sensor device according to the present technology includes a plurality of pixel units arranged in a row direction and a column direction, in which each of the plurality of pixel units includes a plurality of unit pixels arranged in a row direction and a column direction, each of the plurality of unit pixels includes at least one pixel having a photoelectric conversion element and a scattering structure that scatters light incident on the photoelectric conversion element, and at least one of the unit pixels has a different formation pattern of the scattering structure from that of the other unit pixels.

### TECHNICAL FIELD

The present technology relates to a sensor device in which a plurality of pixels each having a photoelectric conversion element is arranged in a row direction and a column direction, and particularly relates to a technology for reducing flare caused by the periodicity of a pattern of a fine structure.

### BACKGROUND ART

For example, a sensor device in which a plurality of pixels each having a photoelectric conversion element is arranged in a row direction and a column direction, such as a charge coupled device (CCD) image sensor or a complementary metal oxide semiconductor (CMOS) image sensor, is widely known.

This type of sensor device has a reflecting surface having a fine periodic structure, and this reflecting surface may produce an effect similar to that of a reflection grating. Reflected light of which intensity is periodically repeated is generated by the reflecting surface, and the reflected light is reflected and received by another optical member, whereby flare occurs.

Patent Document 1 below discloses a technology for reducing flare by forming an antireflection structure as a moth-eye structure on a light incident surface side of a semiconductor substrate on which a photoelectric conversion unit is formed for each of a plurality of pixels.

### CITATION LIST

### Patent Document

Patent Document 1: Japanese Patent Application Laid-Open No. 2015-220313

### SUMMARY OF THE INVENTION

### Problems to be Solved by the Invention

Here, in some sensor devices, a scattering structure is formed for each pixel in order to improve the light receiving efficiency of a photoelectric conversion element. By providing the scattering structure, an optical path length of the light received by the photoelectric conversion element can be increased, and the photoelectric conversion efficiency can be improved.

Such a scattering structure is particularly adopted in an infrared light receiving sensor that receives infrared light. This is because the light receiving sensitivity of the photoelectric conversion element to infrared light tends to be low at present.

However, in a case where a scattering structure is provided for each pixel, flare due to the periodicity of the scattering structure occurs.

The present technology has been made in view of the above circumstances, and an object thereof is to realize reduction of flare due to a scattering structure while improving the efficiency of a manufacturing process of a sensor device.

### Solutions to Problems

A sensor device according to the present technology includes a plurality of pixel units arranged in a row direction and a column direction, in which each of the plurality of pixel units includes a plurality of unit pixels arranged in a row direction and a column direction, each of the plurality of unit pixels includes at least one pixel having a photoelectric conversion element and a scattering structure that scatters light incident on the photoelectric conversion element, and at least one of the unit pixels has a different formation pattern of the scattering structure from that of the other unit pixels.

Making the formation pattern of the scattering structure of some unit pixels different as described above enables the periodicity of the scattering structure to be disturbed. In addition, according to the above configuration, the formation patterns of the scattering structures can be the same in each of the pixel units.

### BRIEF DESCRIPTION OF DRAWINGS

FIG. 1 is a block diagram for describing a configuration example of a distance measuring device including a sensor device as a first embodiment according to the present technology.

FIG. 2 is a block diagram illustrating an internal circuit configuration example of a sensor device (sensor unit) as the first embodiment.

FIG. 3 is an equivalent circuit diagram of a pixel included in the sensor device as the first embodiment.

FIG. 4 is a cross-sectional diagram for describing a schematic structure of a pixel array unit in the first embodiment.

FIG. 5 is a plan view for describing schematic structures of an inter-pixel separation structure and an inter-pixel light shielding structure.

FIG. 6 is a diagram illustrating an example of petal-shaped flare.

FIG. 7 is an explanatory diagram of an occurrence principle of petal-shaped flare.

FIG. 8 is a plan view for describing an example of a formation pattern of a scattering structure in the first embodiment.

FIG. 9 is an explanatory diagram of an example in which the cycle of a scattering structure is smaller than the cycle of a pixel unit.

FIG. 10 is a diagram illustrating a simulation result for describing a flare reduction effect.

FIG. 11 is an explanatory diagram of a flare occurrence position.

FIG. 12 is an explanatory diagram of a light receiving spot radius of a light source that is a flare occurrence source.

FIG. 13 is an explanatory diagram of a modification of a scattering structure formation pattern in the first embodiment.

FIG. 14 is also an explanatory diagram of a modification of a scattering structure formation pattern in the first embodiment.

FIG. 15 is an explanatory diagram of an example in which a chiral shape is adopted as a planar shape of a scattering structure.

FIG. 16 is an explanatory diagram of a modification regarding a size of a pixel unit.

FIG. 17 is a cross-sectional diagram for describing a schematic structure of a pixel array unit in a color image sensor.

FIG. 18 is an explanatory diagram of an example of a formation pattern of a scattering structure in a second embodiment.

### MODE FOR CARRYING OUT THE INVENTION

Hereinafter, embodiments according to the present technology will be described in the following order with reference to the accompanying drawings.
1. First Embodiment
(1-1. Configuration of distance measuring device)
(1-2. Circuit configuration of sensor device)
(1-3. Circuit configuration of pixel)
(1-4. Structure of pixel array unit)
(1-5. Scattering structure formation pattern as embodiment)
(1-6. Other formation pattern examples)
2. Second Embodiment
<3. Modification>
<4. Summary of embodiments>
<5. Present technology>

### 1. First Embodiment

### (1-1. Configuration of Distance Measuring Device)

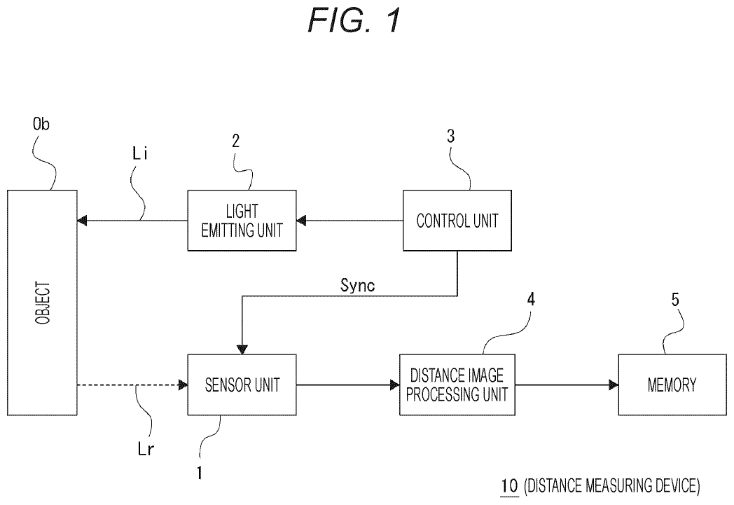

FIG. 1 is a block diagram for describing a configuration example of a distance measuring device 10 including a sensor device as a first embodiment according to the present technology.

As illustrated, the distance measuring device 10 includes a sensor unit 1, a light emitting unit 2, a control unit 3, a distance image processing unit 4, and a memory 5. The distance measuring device 10 is a device that performs distance measurement by a time of flight (ToF) method. Specifically, the distance measuring device 10 of the present example performs distance measurement by an indirect ToF (iToF) method. The indirect ToF method is a distance measuring method of calculating a distance to an object Ob on the basis of a phase difference between irradiation light Li to the object Ob and reflected light Lr obtained by reflection of the irradiation light Li by the object Ob.

The light emitting unit 2 includes one or a plurality of light emitting elements as a light source, and emits the irradiation light Li to the object Ob. In the present example, the light emitting unit 2 emits, for example, infrared light having a wavelength in a range of 780 nm to 1000 nm as the irradiation light Li.

The control unit 3 controls a light emitting operation of the irradiation light Li by the light emitting unit 2. In a case of the indirect ToF method, as the irradiation light Li, used is light having intensity modulated so that the intensity changes periodically in predetermined cycles. Specifically, in the present example, as the irradiation light Li, pulsed light is repeatedly emitted in predetermined cycles. Hereinafter, such a light emitting cycle of the pulsed light is referred to as a “light emitting cycle Cl”. In addition, a period between light emission start timings of the pulsed light when the pulsed light is repeatedly emitted in light emitting cycles Cl is referred to as “one modulation period Pm” or simply a “modulation period Pm”.

The control unit 3 controls the light emitting operation by the light emitting unit 2 such that the light emitting unit 2 emits the irradiation light Li only during a predetermined light emitting period in every modulation period Pm.

Here, in the indirect ToF method, the light emitting cycles Cl are relatively fast, for example, about tens MHz to hundreds MHz.

The sensor unit 1 corresponds to a sensor device as the first embodiment according to the present technology.

The sensor unit 1 receives the reflected light Lr and outputs distance measurement information by the indirect ToF method on the basis of a phase difference between the reflected light Lr and the irradiation light Li.

As will be described later, the sensor unit 1 of the present example includes a pixel array unit 11 in which a plurality of pixels Px each including a photoelectric conversion element (photodiode PD), and a first transfer gate element (transfer transistor TG-A) and a second transfer gate element (transfer transistor TG-B) which are for transferring accumulated charge in the photoelectric conversion element is two-dimensionally arranged, and the sensor unit 1 obtains the distance measurement information by the indirect ToF method for every pixel Px.

Note that, hereinafter, information indicating the distance measurement information (distance information) for every pixel Px as described above is referred to as a “distance image”.

Here, as is known, in the indirect ToF method, signal charge accumulated in the photoelectric conversion element in the pixel Px is distributed into two floating diffusions (FD) by the first transfer gate element and the second transfer gate element which are alternately turned on. At this time, a cycle in which the first transfer gate element and the second transfer gate element are alternately turned on is the same cycle as the light emitting cycle Cl of the light emitting unit 2. That is, each of the first transfer gate element and the second transfer gate element is turned on once in every modulation period Pm, and the distribution of the signal charge into the two floating diffusions as described above is repeatedly performed in every modulation period Pm.

In the present example, the transfer transistor TG-A serving as the first transfer gate element is turned on in the light emitting period of the irradiation light Li in the modulation period Pm, and the transfer transistor TG-B serving as the second transfer gate element is turned on in the non-light emitting period of the irradiation light Li in the modulation period Pm.

As described above, the light emitting cycles Cl are relatively fast, and thus the amount of the signal charge accumulated in each floating diffusion by one distribution using the first and second transfer gate elements as described above is relatively small. For this reason, in the indirect ToF method, the emission of the irradiation light Li is repeated about several thousand times to several tens of thousands of times per distance measurement (that is, in obtaining one distance image), and the sensor unit 1 repeatedly distributes the signal charge into the floating diffusions using the first and second transfer gate elements as described above while the irradiation light Li is repeatedly emitted in this manner.

As understood from the above description, in the sensor unit 1, the first transfer gate element and the second transfer gate element are driven at a timing synchronized with the light emitting cycle of the irradiation light Li for each pixel Px. Thus, to the sensor unit 1, a synchronization signal Sync indicating the timing synchronized with the light emitting cycle Cl is input by the control unit 3, and is used to drive the first and second transfer gate elements in each pixel Px.

The distance image processing unit 4 receives the distance image obtained by the sensor unit 1, performs predetermined signal processing such as compression encoding, for example, and then outputs the distance image to the memory 5.

The memory 5 is a storage device such as a flash memory, a solid state drive (SSD), or a hard disk drive (HDD), for example, and stores the distance image processed by the distance image processing unit 4.

### (1-2. Circuit Configuration of Sensor Device)

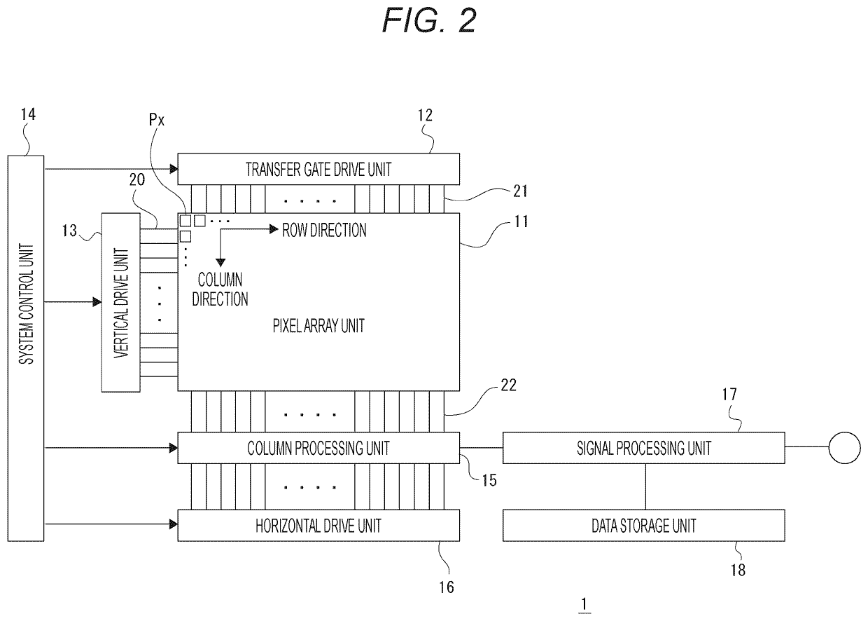

FIG. 2 is a block diagram illustrating an internal circuit configuration example of the sensor unit 1.

As illustrated, the sensor unit 1 includes the pixel array unit 11, a transfer gate drive unit 12, a vertical drive unit 13, a system control unit 14, a column processing unit 15, a horizontal drive unit 16, a signal processing unit 17, and a data storage unit 18.

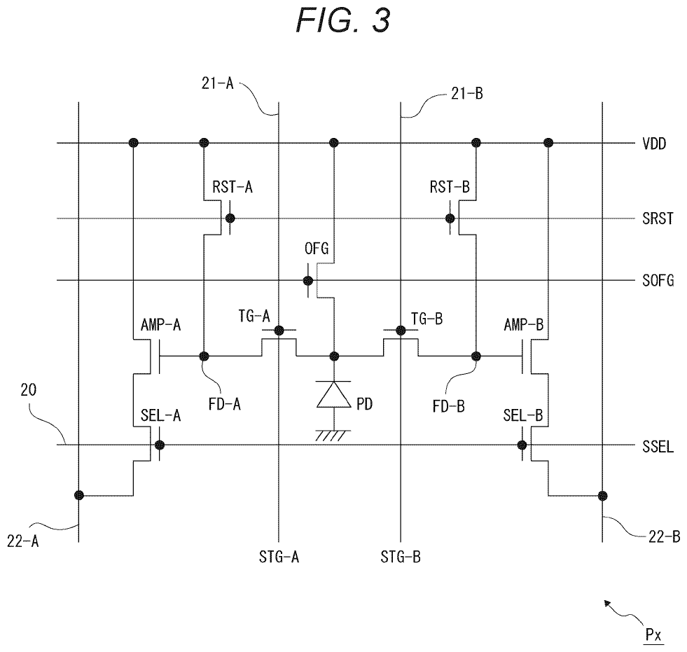

The pixel array unit 11 has a configuration in which a plurality of pixels Px is two-dimensionally arranged in a matrix in a row direction and a column direction. Each pixel Px includes a photodiode PD as described later as a photoelectric conversion element. Note that, details of the pixel Px will be described again with reference to FIG. 3 or the like.

Here, the row direction refers to an arrangement direction of the pixels Px in a horizontal direction, and the column direction refers to an arrangement direction of the pixels Px in a vertical direction. In the drawings, the row direction is a lateral direction, and the column direction is a longitudinal direction.

In the pixel array unit 11, with respect to a matrix-shaped pixel arrangement, a pixel drive line 20 is provided along the row direction for each pixel row, and two gate drive lines 21 and two vertical signal lines 22 are provided for each pixel column along the column direction. For example, the pixel drive line 20 transmits a drive signal for driving the pixel Px when reading a signal from the pixel Px. Note that, the pixel drive line 20 is illustrated as one wiring line in FIG. 2, but the number is not limited to one. One end of the pixel drive line 20 is connected to an output end corresponding to each row of the vertical drive unit 13.

The system control unit 14 includes a timing generator that generates various timing signals and the like, and performs drive control of the transfer gate drive unit 12, the vertical drive unit 13, the column processing unit 15, the horizontal drive unit 16, and the like on the basis of various timing signals generated by the timing generator.

The transfer gate drive unit 12 drives two transfer gate elements provided for every pixel Px through the two gate drive lines 21 provided in each pixel column as described above on the basis of control of the system control unit 14.

As described above, the two transfer gate elements are alternately turned on in every modulation period Pm. Thus, the system control unit 14 controls on/off timings of the two transfer gate elements by the transfer gate drive unit 12 on the basis of the synchronization signal Sync described with reference to FIG. 1.

The vertical drive unit 13 includes a shift register, an address decoder, and the like, and drives all pixels Px of the pixel array unit 11 at the same time, drives the pixels Px in each row, or the like. That is, the vertical drive unit 13 is included in a drive unit that controls an operation of each pixel Px of the pixel array unit 11 together with the system control unit 14 that controls the vertical drive unit 13.

A detection signal output (read) from each pixel Px of the pixel row according to drive control by the vertical drive unit 13, specifically, a signal corresponding to the signal charge accumulated in each of the two floating diffusions provided for every pixel Px is input to the column processing unit 15 through the corresponding vertical signal lines 22. The column processing unit 15 performs predetermined signal processing on the detection signal read from each pixel Px through the vertical signal lines 22, and temporarily holds the detection signal after the signal processing. Specifically, the column processing unit 15 performs noise removal processing, analog to digital (A/D) conversion processing, or the like as signal processing.

Here, reading of two detection signals (detection signals for the respective floating diffusions) from each pixel Px is performed once every predetermined number of repeated light emission of the irradiation light Li (every several thousand times to several tens of thousands of times of repeated light emission described above).

Therefore, the system control unit 14 also controls the vertical drive unit 13 on the basis of the synchronization signal Sync for timing of reading the detection signals from each pixel Px.

The horizontal drive unit 16 includes a shift register, an address decoder, and the like, and sequentially selects unit circuits corresponding to pixel columns of the column processing unit 15. Selective scanning by the horizontal drive unit 16 sequentially outputs detection signals obtained by the signal processing for each unit circuit in the column processing unit 15.

The signal processing unit 17 has at least an arithmetic processing function, and performs various types of signal processing such as calculation processing of a distance corresponding to the indirect ToF method on the basis of the detection signals output from the column processing unit 15. Note that, a known method can be used as a method of calculating distance information by the indirect ToF method on the basis of two types of detection signals (detection signals for the respective floating diffusions) for every pixel Px, and the description thereof will be omitted here.

The data storage unit 18 temporarily stores data necessary for signal processing in the signal processing unit 17.

The sensor unit 1 configured as described above outputs a distance image indicating the distance to the object Ob for every pixel Px. The distance image enables the three-dimensional shape of the object Ob to be recognized.

### (1-3. Circuit Configuration of Pixel)

FIG. 3 illustrates an equivalent circuit of the pixel Px in a two-dimensional arrangement in the pixel array unit 11.

The pixel Px includes one photodiode PD serving as a photoelectric conversion element and one overflow (OF) gate transistor OFG. In addition, the pixel Px includes two transfer transistors TG serving as the transfer gate elements, two floating diffusions FD, two reset transistors RST, two amplification transistors AMP, and two selection transistors SEL.

Here, in a case where each of the two transfer transistors TG, the two floating diffusions FD, the two reset transistors RST, the two amplification transistors AMP, and the two selection transistors SEL provided in the pixel Px are distinguished from each other, as illustrated in FIG. 3, they are denoted as transfer transistors TG-A and TG-B, floating diffusions FD-A and FD-B, reset transistors RST-A and RST-B, amplification transistors AMP-A and AMP-B, and selection transistors SEL-A and SEL-B.

The OF gate transistor OFG, the transfer transistors TG, the reset transistors RST, the amplification transistors AMP, and the selection transistors SEL each include, for example, an N-type MOS transistor.

When an OF gate signal SOFG supplied to the gate is turned on, the OF gate transistor OFG becomes conductive. When the OF gate transistor OFG becomes conductive, the photodiode PD is clamped to a predetermined reference potential VDD, and accumulated charge is reset.

Note that, the OF gate signal SOFG is supplied from the vertical drive unit 13, for example.

The transfer transistor TG-A becomes conductive when a transfer drive signal STG-A supplied to the gate is turned on, and transfers the signal charge accumulated in the photodiode PD to the floating diffusion FD-A. The transfer transistor TG-B becomes conductive when a transfer drive signal STG-B supplied to the gate is turned on, and transfers the charge accumulated in the photodiode PD to the floating diffusion FD-B.

The transfer drive signals STG-A and STG-B are supplied from the transfer gate drive unit 12 through gate drive lines 21-A and 21-B, each of which is provided as one of the gate drive lines 21 illustrated in FIG. 2.

The floating diffusions FD-A and FD-B are charge holding units that temporarily hold the charge transferred from the photodiode PD.

The reset transistor RST-A becomes conductive when a reset signal SRST supplied to the gate is turned on, and resets the potential of the floating diffusion FD-A to the reference potential VDD. Similarly, the reset transistor RST-B becomes conductive when the reset signal SRST supplied to the gate is turned on, and resets the potential of the floating diffusion FD-B to the reference potential VDD.

Note that, the reset signal SRST is supplied from the vertical drive unit 13, for example.

The amplification transistor AMP-A has a source connected to a vertical signal line 22-A via the selection transistor SEL-A, and a drain connected to the reference potential VDD (constant current source) to form a source follower circuit. The amplification transistor AMP-B has a source connected to a vertical signal line 22-B via the selection transistor SEL-B and a drain connected to the reference potential VDD (constant current source) to form a source follower circuit.

Here, each of the vertical signal lines 22-A and 22-B is provided as one of the vertical signal lines 22 illustrated in FIG. 2.

The selection transistor SEL-A is connected between the source of the amplification transistor AMP-A and the vertical signal line 22-A, becomes conductive when a selection signal SSEL supplied to the gate is turned on, and outputs the charge held in the floating diffusion FD-A to the vertical signal line 22-A via the amplification transistor AMP-A.

The selection transistor SEL-B is connected between the source of the amplification transistor AMP-B and the vertical signal line 22-B, becomes conductive when the selection signal SSEL supplied to the gate is turned on, and outputs the charge held in the floating diffusion FD-B to the vertical signal line 22-B via the amplification transistor AMP-A.

Note that, the selection signal SSEL is supplied from the vertical drive unit 13 via the pixel drive line 20.

Operations of the pixel Px will be briefly described.

First, before light reception is started, a reset operation for resetting the charge in the pixel Px is performed on all pixels. That is, for example, the OF gate transistor OFG, each reset transistor RST, and each transfer transistor TG are turned on (conductive state), so that the accumulated charge in the photodiode PD and each floating diffusion FD is reset.

After the accumulated charge is reset, a light receiving operation for distance measurement is started on all pixels. The light receiving operation described here means a light receiving operation performed for one distance measurement. That is, during the light receiving operation, an operation of alternately turning on the transfer transistors TG-A and TG-B is repeated a predetermined number of times (in the present example, about several thousand times to several tens of thousands of times). Hereinafter, a period of the light receiving operation performed for such one distance measurement is referred to as a “light receiving period Pr”.

In the light receiving period Pr, in one modulation period Pm of the light emitting unit 2, for example, after a period in which the transfer transistor TG-A is on (that is, a period in which the transfer transistor TG-B is off) is continued over a light emitting period of the irradiation light Li, the remaining period, that is, a non-light emitting period of the irradiation light Li is a period in which the transfer transistor TG-B is on (that is, a period in which the transfer transistor TG-A is off). That is, in the light receiving period Pr, an operation of distributing the charge of the photodiode PD into the floating diffusions FD-A and FD-B within one modulation period Pm is repeated a predetermined number of times.

Then, when the light receiving period Pr ends, pixels Px of the pixel array unit 11 are line-sequentially selected. In each of the selected pixels Px, the selection transistors SEL-A and SEL-B are turned on. As a result, the charge accumulated in the floating diffusion FD-A is output to the column processing unit 15 via the vertical signal line 22-A. In addition, the charge accumulated in the floating diffusion FD-B is output to the column processing unit 15 via the vertical signal line 22-B.

One light receiving operation has been described, and the next light receiving operation starts again from the reset operation.

Here, reception of reflected light by the pixel Px is delayed according to the distance to the object Ob from the timing at which the light emitting unit 2 emits the irradiation light Li. Depending on a delay time according to the distance to the object Ob, a distribution ratio of the charge accumulated in the two floating diffusions FD-A and FD-B changes, and thus the distance to the object Ob can be obtained from the distribution ratio of the charge accumulated in these two floating diffusions FD-A and FD-B.

### (1-4. Structure of Pixel Array Unit)

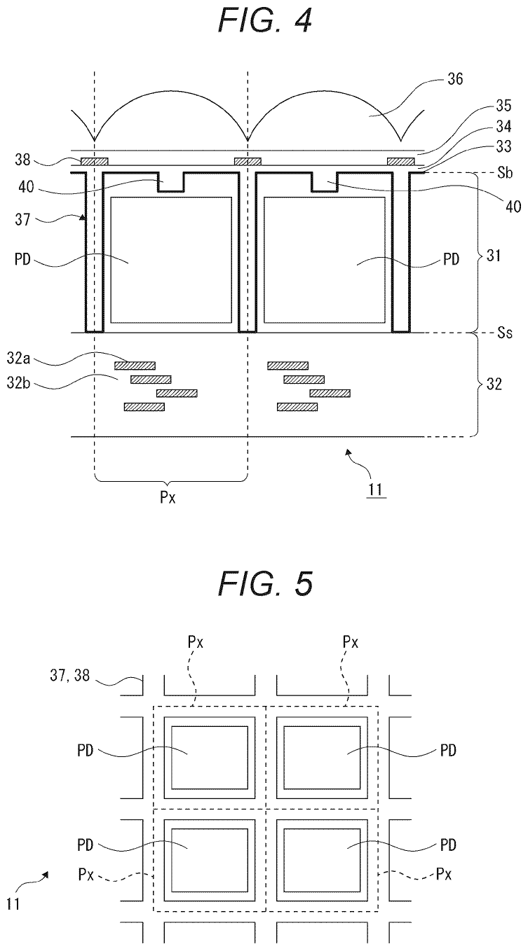

FIG. 4 is a cross-sectional diagram for describing a schematic structure of the pixel array unit 11.

The sensor unit 1 according to the present embodiment has a configuration as a back surface illuminated type complementary metal oxide semiconductor (CMOS) type solid-state imaging element. The “back surface” referred here is defined with a front surface Ss and a back surface Sb of a semiconductor substrate 31 included in the pixel array unit 11 as references.

As illustrated in FIG. 4, the pixel array unit 11 includes the semiconductor substrate 31 and a wiring layer 32 formed on the front surface Ss side of the semiconductor substrate 31. A fixed charge film 33 which is an insulation film having fixed charge is formed on the back surface Sb of the semiconductor substrate 31, and an insulation film 34 is formed on the fixed charge film 33. In addition, on the insulation film 34, an inter-pixel light shielding unit 38, a planarization film 35, and a microlens (on-chip lens) 36 are stacked in this order.

Note that, although the above-described various transistors (transfer transistors TG, reset transistors RST, amplification transistors AMP, selection transistors SEL, and OF gate transistor OFG) are also formed in each pixel Px, these transistors are not illustrated in FIG. 4. Conductors functioning as electrodes (electrodes including gates, drains, and sources) of these transistors are formed in the wiring layer 32 near the front surface Ss of the semiconductor substrate 31.

The semiconductor substrate 31 is made of, for example, silicon (Si), and is formed to have a thickness of, for example, about 1 μm to 6 μm. In the semiconductor substrate 31, the photodiode PD as a photoelectric conversion element is formed in a region of each pixel Px. Adjacent photodiodes PD are electrically separated by an inter-pixel separation unit 37.

The inter-pixel separation unit 37 includes a part of the fixed charge film 33 and a part of the insulation film 34, and is formed in a grid shape so as to surround the photodiode PD of each pixel Px as exemplified in the plan view of FIG. 5. With such a configuration, the inter-pixel separation unit 37 has a function of electrically separating the pixels Px so that the signal charge leakage does not occur between the pixels Px.

Here, the inter-pixel separation unit 37 can be formed by forming the fixed charge film 33 and the insulation film 34 in trench (groove) formed in the semiconductor substrate 31 so as to surround formation regions of the photodiodes PD (so-called trench isolation). Specifically, the inter-pixel separation unit 37 can be configured as, for example, a front deep trench isolation(FDTI), a front full trench isolation (FFTI), a reversed deep trench isolation (RDTI), a reversed full trench isolation (RFTI), or the like.

Note that, “front” and “reversed” referred here indicates whether cutting for forming the trench is performed from the front surface Ss side or the back surface Sb side of the semiconductor substrate 31. In addition, “deep” and“full” indicate the depth (groove depth) of the trench. “Full” means that the trench penetrates the semiconductor substrate 31, and “deep” means that the trench is formed at a depth that does not penetrate the semiconductor substrate 31.

FIG. 4 exemplifies a structure corresponding to the RDTI or the RFTI in which the trench is formed from the back surface Sb side.

Note that, in a case where the trench is formed in the semiconductor substrate 31, a width of the trench tends to gradually become narrower toward a progressing direction of cutting. Therefore, in a case where the trench is formed from the front surface Ss side as in the FDTI or the FFTI, the inter-pixel separation unit 37 has a feature that the width is narrower on the back surface Sb side than on the front surface Ss side. Conversely, in a case where the trench is formed from the back surface Sb side as in the RDTI or the RFTI, the inter-pixel separation unit 37 has a feature that the width is narrower on the front surface Ss side than on the back surface Sb side.

The fixed charge film 33 is formed on the sidewall surface and the bottom surface of the trench described above and is formed on the entire back surface Sb of the semiconductor substrate 31 in the process of forming the inter-pixel separation unit 37. As the fixed charge film 33, it is preferable to use a material that can enhance pinning by generating fixed charge by being deposited on a substrate such as silicon, and a high refractive index material film or a high dielectric film having negative charge can be used. As a specific material, an oxide or nitride containing at least any one of elements, for example, hafnium (Hf), aluminum (Al), zirconium (Zr), tantalum (Ta), or titanium (Ti), can be applied. Examples of a film forming method include a chemical vapor deposition (CVD) method, a sputtering method, an atomic layer deposition (ALD) method, and the like. Note that, if the ALD method is used, a silicon oxide (SiO₂) film that reduces an interface state during a film formation can be formed to have a film thickness of about 1 nm at the same time.

Note that, silicon or nitrogen (N) may be added to a material of the fixed charge film 33 within a range where insulation properties thereof are not impaired. The concentration thereof is appropriately determined within a range where the insulation properties of the film are not impaired. As described above, the addition of silicon or nitrogen (N) makes it possible to increase the heat resistance of the film and the ability to prevent ion implantation during the process.

In the present embodiment, the fixed charge film 33 having negative charge is formed inside the inter-pixel separation unit 37 and on the back surface Sb of the semiconductor substrate 31, and thus an inversion layer is formed on a surface in contact with the fixed charge film 33. Therefore, a silicon interface is pinned by the inversion layer, and thus generation of a dark current is suppressed. In addition, in a case where a trench for forming the inter-pixel separation unit 37 is formed in the semiconductor substrate 31, there is a possibility that physical damage occurs on the sidewall and the bottom surface of the trench, and unpinning occurs in the peripheral part of the trench. However, in order to resolve this issue, in the present example, the fixed charge film 33 having a large amount of fixed charge is formed on the sidewall surface and the bottom surface of the trench to prevent unpinning.

The insulating film 34 is embedded in the trench in which the fixed charge film 33 is formed, and is formed on the entire back surface Sb side of the semiconductor substrate 31. The material of the insulation film 34 is preferably a material having a refractive index different from that of the fixed charge film 33, and for example, silicon oxide, silicon nitride, silicon oxynitride, resin, or the like can be used. In addition, a material having a feature of not having positive fixed charge or having a small amount of positive fixed charge can be used for the insulation film 34.

In the present embodiment, the insulation film 34 is embedded inside the inter-pixel separation unit 37, and thus the photodiodes PD in the pixels Px are separated by the insulation film 34. With this configuration, the signal charge is less likely to leak into adjacent pixels, and thus, in a case where the signal charge exceeding a saturated charge amount (Qs) is generated, the overflowed signal charge can be suppressed from leaking into the adjacent photodiodes PD.

In addition, in the present embodiment, the two-layer structure of the fixed charge film 33 and the insulation film 34 formed on the back surface Sb side which is the light incident surface side of the semiconductor substrate 31 also functions as an antireflection film by a difference in refractive index therebetween.

On the insulation film 34 formed on the back surface Sb side of the semiconductor substrate 31, the inter-pixel light shielding unit 38 is formed in a grid shape so as to open at the photodiodes PD of the respective pixels Px. That is, as exemplified in the plan view of FIG. 5, the inter-pixel light shielding unit 38 is formed at a position corresponding to the inter-pixel separation unit 37.

A material of which the inter-pixel light shielding unit 38 is made is only required to be a material capable of shielding light. For example, tungsten (W), aluminum (Al), or copper (Cu) can be used.

Between adjacent pixels Px, the inter-pixel light shielding unit 38 prevents light to be incident only on one pixel Px from leaking into the other pixel Px.

The planarization film 35 is formed on the inter-pixel light shielding unit 38 and on a region of the insulation film 34 where the inter-pixel light shielding unit 38 is not formed, whereby the surface of the semiconductor substrate 31 on the back surface Sb side is planarized. As a material of the planarization film 35, for example, an organic material such as resin can be used.

The microlens 36 is formed on the planarization film 35 for every pixel Px. The microlens 36 condenses incident light, and the condensed light is efficiently incident on the photodiode PD.

The wiring layer 32 is formed on the front surface Ss side of the semiconductor substrate 31, and includes a plurality of layers of wirings 32a stacked via an interlayer insulation film 32b. Via the wirings 32a formed in the wiring layer 32, various transistors such as the above-described transfer transistor TG are driven.

In addition, in the pixel Px, a scattering structure 40 is formed.

The scattering structure 40 is formed on the back surface Sb side of the semiconductor substrate 31 (that is, the light incident surface side) and has a function of scattering light incident on the photodiode PD. In the present example, the scattering structure 40 is formed by digging a groove portion in the back surface Sb of the semiconductor substrate 31. Specifically, the scattering structure 40 in the present example is formed by forming the fixed charge film 33 described above on the sidewall surface and the bottom surface of the groove portion formed in the back surface Sb of the semiconductor substrate 31 and then forming the insulation film 34 on the fixed charge film 33.

Note that, the specific structure of the scattering structure 40 is not limited to the structure exemplified above. As the scattering structure 40, any structure formed on the light incident surface side of the semiconductor substrate 31 and having a function of scattering light incident on the photodiode PD can be used.

In the sensor unit 1 including the pixel array unit 11 as described above, light is emitted to the back surface Sb side of the semiconductor substrate 31, and the light that has been transmitted through the microlens 36 is photoelectrically converted by the photodiode PD, whereby signal charge is generated. At this time, since the scattering structure 40 is provided, an optical path length of light incident on the photodiode PD can be increased, enabling improvement of photoelectric conversion efficiency in the photodiode PD.

Then, a pixel signal based on the signal charge obtained by the photoelectric conversion is output through the transfer transistor TG, the amplification transistor AMP, or the selection transistor SEL formed on the front surface Ss side of the semiconductor substrate 31, via the vertical signal lines 22 formed as predetermined wirings 32a in the wiring layer 32.

### (1-5. Scattering Structure Formation Pattern as Embodiment)

Here, as described above, the sensor unit 1 according to the present embodiment has the scattering structure 40 for every pixel Px, but if the formation patterns of the scattering structures 40 are the same in the respective pixels Px, the occurrence of flare due to the periodicity of the scattering structure 40 is promoted.

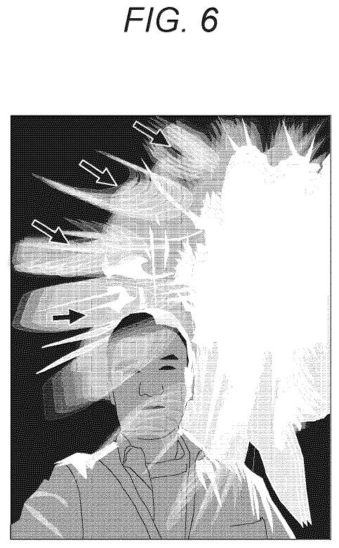

In particular, as the flare due to the periodicity of the scattering structure 40, for example, petal-shaped flare as exemplified in FIG. 6 occurs. In a case where a high brightness light source is captured within the angle of view, such petal-shaped flare in a petal shape occurs as indicated by an arrow in the figure substantially radially from a light receiving spot of the light source.

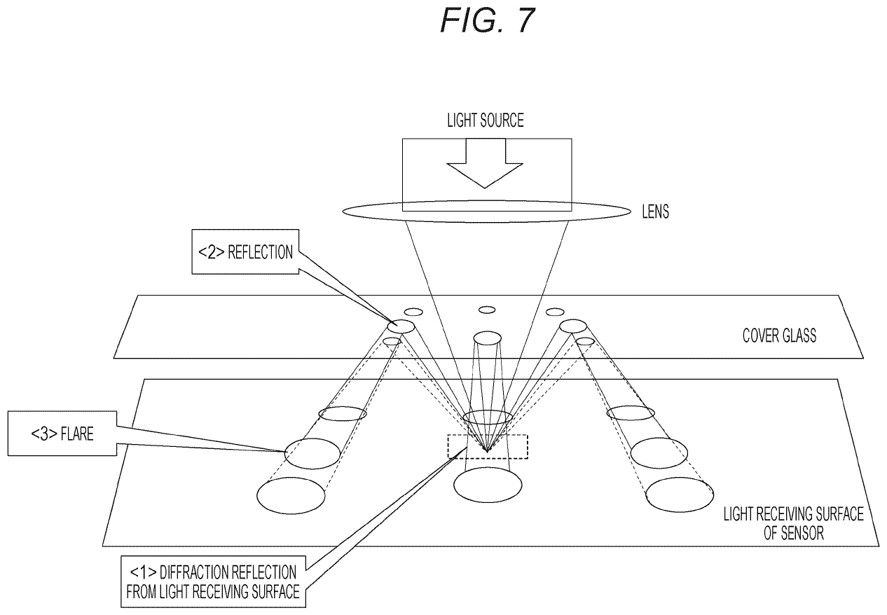

FIG. 7 is an explanatory diagram of an occurrence principle of the petal-shaped flare.

FIG. 7 schematically illustrates a lens (imaging lens) for condensing light from a subject and guiding the light to a light receiving surface of the sensor unit 1, the light receiving surface of the sensor unit 1 (in the figure, the light receiving surface of the sensor), and a cover glass of the sensor unit 1 located between the lens and the light receiving surface. Although not illustrated, an infrared (IR) filter that selectively transmits infrared light is formed on a surface side of the cover glass facing the light receiving surface. In the present example, the IR filter causes the photodiode PD in each pixel Px to receive infrared light.

When light from the light source is irradiated to the light receiving surface through the lens, diffraction reflection from the light receiving surface occurs (<1> in the figure), the diffracted and reflected light is reflected by the IR filter portion of the cover glass (<2> in the figure), and the reflected light is irradiated to the light receiving surface again to generate flare (<3> in the figure).

In order to reduce such flare, in the present embodiment, the periodicity of the scattering structure 40 is disturbed, that is, the cycle of the scattering structure 40 is set to be larger than the cycle of each pixel Px.

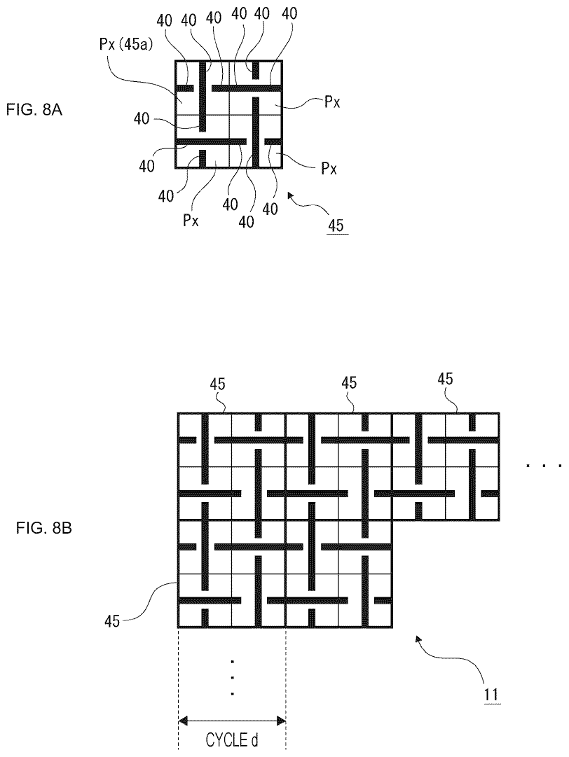

FIG. 8 is a plan view for describing an example of a formation pattern of the scattering structure 40 in the present embodiment.

First, in the present embodiment, terms, a pixel unit 45 and a unit pixel 45a are used.

The unit pixel 45a means an element including at least one pixel having a photoelectric conversion element and a scattering structure that scatters light incident on the photoelectric conversion element. That is, in the present example, the unit pixel 45a includes at least one pixel Px.

In the first embodiment, it is assumed that the unit pixel 45a includes only one pixel Px, that is, the unit pixel 45a and the pixel Px are equivalent.

The pixel unit 45 means an element formed by arranging a plurality of unit pixels 45a in the row direction and the column direction.

In the present embodiment, in the pixel unit 45, at least one unit pixel 45a is different from the other unit pixels 45a in the formation pattern of the scattering structure 40. Then, the pixel array unit 11 according to the present embodiment is formed by arranging a plurality of such pixel units 45 in the row direction and the column direction.

Specifically, as illustrated in FIG. 8A, the pixel unit 45 in the present example includes four pixels Px (unit pixels 45a) of the row direction×the column direction=2×2=4. Then, in the pixel unit 45, the planar shape of the scattering structure 40 in each pixel Px is a rotationally symmetric shape, and the scattering structure 40 in at least one pixel Px is formed at a rotation angle different from that of the other pixels Px.

Specifically, in the present example, a planar shape of “+” is adopted as the planar shape of the scattering structure 40 in each pixel Px. This planar shape of substantially “+” is a rotationally symmetric shape of 2-fold symmetry because the shape completely matches every time when rotated by 180 degrees. Then, in the pixel unit 45 in the present example, as exemplified in FIG. 8A, the scattering structures 40 having the planar shape of substantially “+” are arranged with the rotation angle being rotated by 90 degrees between the pixels Px. Specifically, in the present example, the scattering structure 40 in each pixel Px is formed such that the rotation angle is shifted by 90 degrees between the adjacent pixels Px in both the row direction and the column direction.

Here, the planar shape of the scattering structure 40 is rotationally symmetric shape, and thus the planar sizes of the scattering structures 40 in the respective pixels Px are the same.

Then, the pixel array unit 11 in the present example is formed by arranging a plurality of the pixel units 45 illustrated in FIG. 8A in the row direction and the column direction.

Note that, as understood from the fact that the same reference signs are given to the respective pixel units 45, in the present embodiment, the formation patterns of the scattering structures 40 in the respective pixel units 45 are the same.

In this case, a pattern cycle (hereinafter, referred to as “cycle d”) of the scattering structure 40 in the pixel array unit 11 is the same as the formation cycle of the pixel unit 45 in both the row direction and the column direction. That is, the cycle corresponds to two pixels.

Therefore, the periodicity of the scattering structure 40 can be disturbed, and flare can be reduced.

In addition, according to the above configuration, the formation patterns of the scattering structures are the same in each of the pixel units 45. Therefore, when reducing the flare, it is possible to improve the efficiency of the manufacturing process of the sensor unit 1.

Furthermore, in the present embodiment, a rotationally symmetric shape is adopted as the planar shape of the scattering structure 40. As a result, the planar shapes and sizes of the scattering structures 40 are the same in the respective pixels Px (unit pixels 45a).

As described above, the planar shapes and the sizes of the scattering structures 40 are the same in the respective pixels Px (unit pixels 45a), so that the light receiving efficiency improving effects by the scattering structure 40 can be equalized in the respective pixels Px, and the variation in the light receiving efficiency between the pixels Px can be reduced.

Here, in setting the formation pattern of the scattering structure 40 in each of the pixel units 45, the cycle of the scattering structure 40 should be prevented from becoming smaller than the cycle of the pixel unit 45 in both the row direction and the column direction.

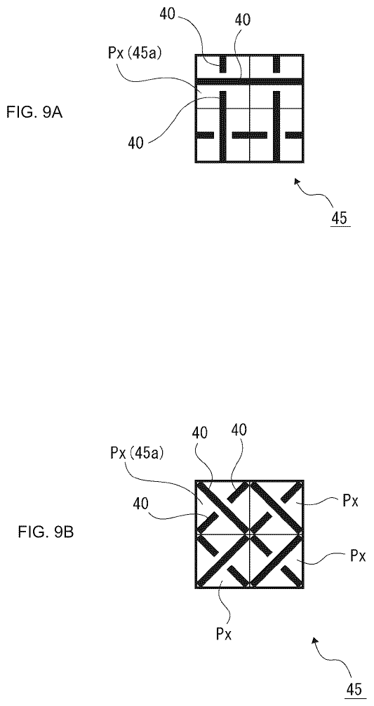

For example, in the examples illustrated in FIGS. 9A and 9B, the scattering structure 40 having the rotationally symmetric shape has a relationship of a 90-degree shift between the adjacent pixels Px in the column direction, but the formation patterns of the scattering structures 40 of the adjacent pixels Px in the row direction match. Therefore, the cycle of the scattering structure 40 corresponds to the cycle of the pixel unit 45 in the column direction, but the cycle of the scattering structure 40 corresponds to the cycle of one pixel in the row direction, and the cycle of the scattering structure 40 cannot be disturbed in the row direction.

Therefore, in the present embodiment, as exemplified in FIG. 8 above, in each of the pixel units 45, there is a row in which the formation pattern of the scattering structures 40 in the row as a unit is different from that in the other rows, and there is a column in which the formation pattern of the scattering structures 40 in the column as a unit is different from that in the other columns.

In this way, it is possible to prevent the cycle of the scattering structure 40 from becoming smaller than the cycle of the pixel unit 45 in both the row direction and the column direction, and to improve the flare reduction effect.

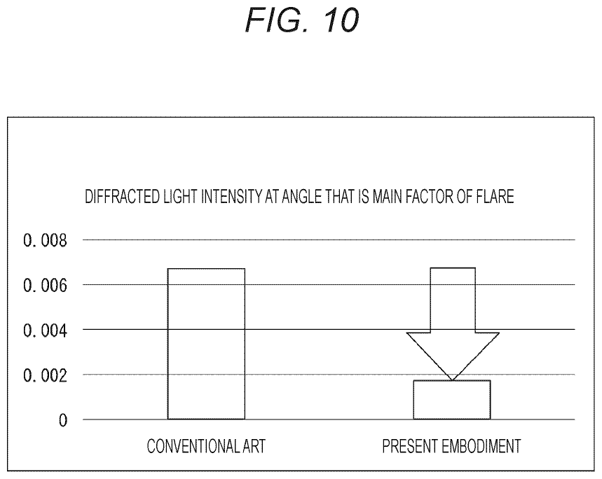

FIG. 10 illustrates a simulation result for describing the flare reduction effect.

Specifically, in FIG. 10, as a conventional example, a simulation result of the diffracted light intensity at an angle that is a main factor of flare in a case where the cycle of the pattern of the scattering structure 40 is the cycle of one pixel, and as the present embodiment, a simulation result of the diffracted light intensity in a case where the cycle of the pattern of the scattering structure 40 is the cycle of the pixel unit 45 as in the sensor unit 1 are illustrated in contrast with each other.

As can be seen with reference to these results, according to the present embodiment, it can be seen that flare can be significantly reduced as compared with the conventional art.

Here, adjustment of the pattern cycle of the scattering structure 40 enables adjustment of the diffraction angle of the diffracted light that causes flare.

In view of this point, in the present embodiment, the cycle of the scattering structure 40 is set such that flare due to low-order diffracted light, for example, +1st order diffracted light or the like is hidden in the light receiving spot of the light source on the light receiving surface.

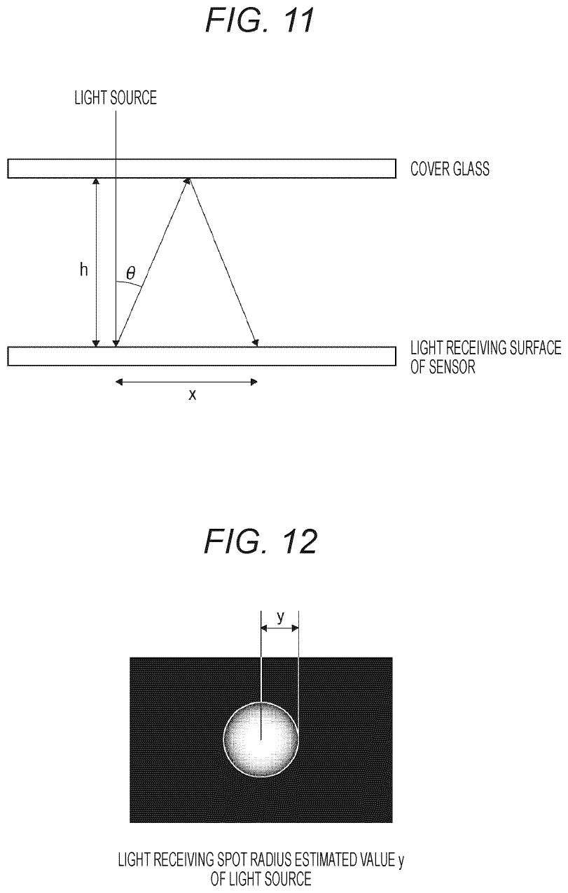

With reference to FIGS. 11 and 12, a condition for hiding the flare caused by the m-th order diffracted light in the light receiving spot of the light source will be considered.

As illustrated in FIG. 11, the diffraction angle of the diffracted light of the diffraction order=m generated on the light receiving surface of the sensor unit 1 is defined as 0, and the distance between the light receiving surface and the reflecting surface of the diffracted light (in the present example, a surface of the cover glass facing the light receiving surface) is defined as h. In addition, the distance from the light receiving spot center of the light source on the light receiving surface to the position where the flare occurs due to the diffracted light of diffraction order=m is defined as x.

At this time, the distance x can be expressed by the following [Expression 1].

$$\begin{matrix}[ Math . 1 ] & \\ x = 2 h \cdot tan θ & [ Expression 1 ]\end{matrix}$$

As illustrated in FIG. 12, when the light receiving spot radius of the light source to be the occurrence source of the flare is defined as y, in order to hide the flare caused by the diffracted light of the diffraction order=m in the light receiving spot of the light source, only the following [Expression 2] is required to be satisfied.

Note that, as the light receiving spot radius y, a predetermined estimated value is used.

$$\begin{matrix}[ Math . 2 ] & \\ 2 h \cdot tan θ ≦ y & [ Expression 2 ]\end{matrix}$$

Here, when the pattern cycle of the scattering structure 40 (formation cycle of the pixel unit 45) is defined as d, and the wavelength of light received on the light receiving surface is defined as λ, the diffraction angle θ=Sin⁻¹ (mλ/d) is satisfied. Thus, the above [Expression 2] can be converted into the following expressions.

$$tan θ ≦ \frac{y}{2 h} \qquad [ Math . 3 ]$$

$$tan θ ( {Sin}^{- 1} \cdot \frac{m λ}{d} ) ≦ \frac{y}{2 h} \qquad [ Math . 4 ]$$

$${Sin}^{- 1} \cdot \frac{m λ}{d} ≦ {Tan}^{- 1} \cdot \frac{y}{2 h} \qquad [ Math . 5 ]$$

$$\frac{m λ}{d} ≦ Sin \cdot {Tan}^{- 1} \cdot \frac{y}{2 h} \qquad [ Math . 6 ]$$

$$m λ ≦ Sin \cdot {Tan}^{- 1} \cdot \frac{y}{2 h} \cdot d \qquad [ Math . 7 ]$$

Therefore, the cycle d satisfying [Expression 2] is expressed by the following [Expression 3].

$$\begin{matrix}[ Math . 8 ] & \\ d ≧ \frac{m λ}{Sin \cdot {Tan}^{- 1} \cdot \frac{y}{2 h}} & [ Expression 3 ]\end{matrix}$$

In the sensor unit 1 according to the present embodiment, the cycle d is set so as to satisfy the above [Expression 3].

As a result, diffracted light of up to ±m-th order can be hidden in the light receiving spot of the light source, and deterioration in sensing accuracy due to the flare can be suppressed.

### (1-6. Other Formation Pattern Examples)

Here, the formation pattern of the scattering structure 40 is not limited to those exemplified in FIG. 8 above, and various patterns are applicable.

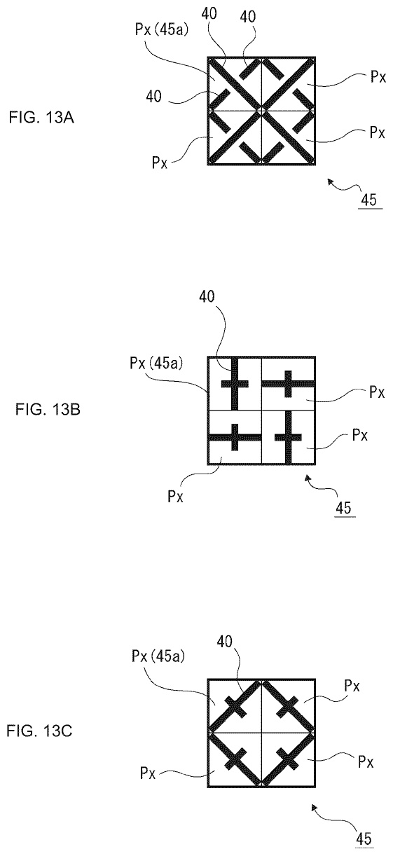

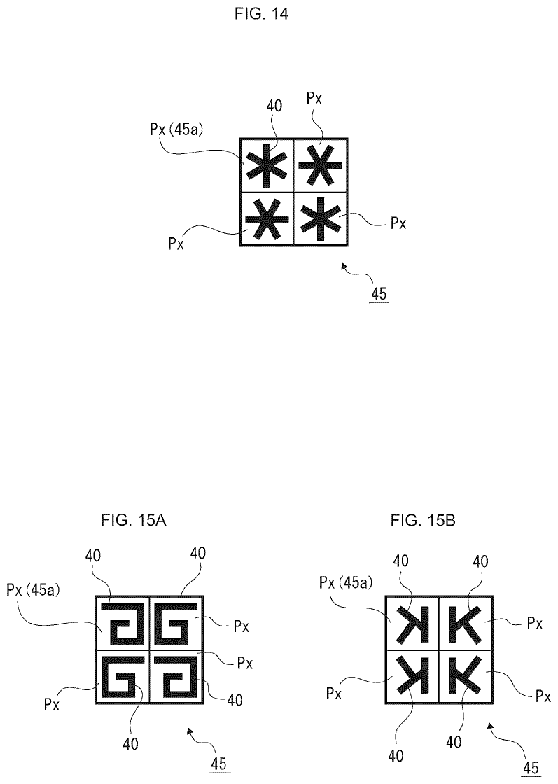

For example, the formation patterns exemplified in FIGS. 13 and 14 can be included in the example.

In FIG. 13, FIG. 13A illustrates another example in which the substantially “+” shape is adopted as a rotationally symmetric shape. Specifically, the case of FIG. 8 is an example in which the rotation angle of the scattering structure 40 is made different between the pixels Px (unit pixels 45a) by 45 degrees.

FIG. 13B illustrates an example in which a substantially cross shape is adopted as a rotationally symmetric shape. Specifically, in the pixel unit 45 in this case, the scattering structures 40 having a planar shape of substantially cross shape are arranged with the rotation angle shifted by 90 degrees between the pixels Px (unit pixels 45a).

In addition, FIG. 13C illustrates another example in which a substantially cross shape is adopted as a rotationally symmetric shape, and the rotation angles of the scattering structures 40 in the respective pixels Px (unit pixels 45a) are made different by 45 degrees from that in the case of FIG. 13B.

FIG. 14 illustrates an example in which substantially “* (asterisk)” shape is adopted as a rotationally symmetric shape, and specifically, in the pixel unit 45 in this case, the scattering structures 40 having a planar shape of substantially “*” shape are arranged with the rotation angle shifted by 90 degrees between the pixels Px (unit pixels 45a).

Each example of FIGS. 13A to 13C and 14 described above is an example in which, in each of the pixel units 45, there is a row in which the formation pattern of the scattering structures 40 in the row as a unit is different from that in the other rows, and there is a column in which the formation pattern of the scattering structures 40 in the column as a unit is different from that in the other columns.

Here, the rotationally symmetric shape is not limited to the 2-fold symmetric shape exemplified above. In the present embodiment, as the rotationally symmetric shape, a shape that is {(2n−1)×2}-fold symmetric (that is, 2-fold symmetric, 6-fold symmetric, 10-fold symmetric, 14-fold symmetric, and so on) can be adopted.

FIG. 15 illustrates an example in which a chiral shape is adopted as a planar shape of the scattering structure 40.

The chiral shape means a shape having chirality.

The pixel unit 45 illustrated in FIG. 15A is an example in which the scattering structures 40 having chiral shapes different between rows are arranged. Specifically, in the example of FIG. 15A, in the pixel unit 45 including 2×2=4 pixels, the scattering structures 40 having a first chiral shape are arranged in two pixels Px (unit pixels 45a) located in the upper row, and the scattering structures 40 having a second chiral shape different from the first chiral shape are arranged in two pixels Px (unit pixels 45a) located in the lower row.

FIG. 15B illustrates an example in which a substantially k shape is adopted as a chiral shape. Specifically, in the pixel unit 45 in this case, by adopting the substantially k shape, the chirality of the scattering structure 40 is realized in both the row direction and the column direction.

Also in the case of adopting the chiral shape as described above, similarly to the case of adopting the rotationally symmetric shape, the variation in the light receiving efficiency between the pixels Px can be reduced. In addition, by adopting a chiral shape, the periodicity of the scattering structure 40 can be disturbed, and the flare also can be reduced.

Each example illustrated in FIGS. 15A and 15B is also an example in which, in each of the pixel units 45, there is a row in which the formation pattern of the scattering structures 40 in the row as a unit is different from that in the other rows, and there is a column in which the formation pattern of the scattering structures 40 in the column as a unit is different from that in the other columns.

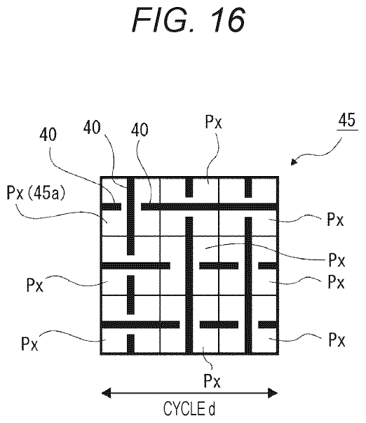

FIG. 16 is an explanatory diagram of a modification regarding the size of the pixel unit 45.

FIG. 16 illustrates an example in which the pixel unit 45 includes 3×3=9 pixels Px.

Here, an example is illustrated in which a rotationally symmetric shape is adopted as the planar shape of the scattering structure 40, but it is also possible to adopt a chiral shape as exemplified in FIG. 15.

In addition, also in this case, in the pixel unit 45, as illustrated, there is a row in which the formation pattern of the scattering structures 40 in the row as a unit is different from that in the other rows, and there is a column in which the formation pattern of the scattering structures 40 in the column as a unit is different from that in the other columns. As a result, the flare reduction effect can be improved.

Note that, the size of the pixel unit 45 is not limited to 2×2=4 or 3×3=9. The pixel unit 45 may be formed by a plurality of unit pixels 45a arranged in the row direction and the column direction.

### 2. Second Embodiment

Next, a second embodiment will be described.

The second embodiment is an application example to a color image sensor. The color image sensor here means an image sensor that obtains a color image as a captured image.

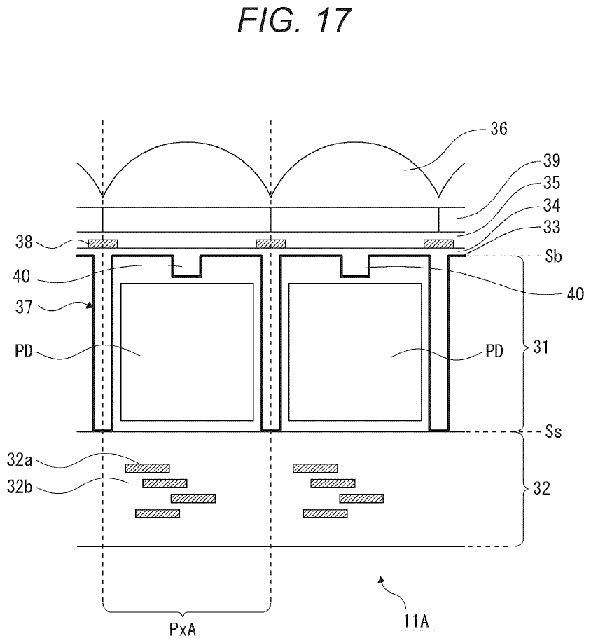

FIG. 17 is a cross-sectional diagram for describing a schematic structure of a pixel array unit 11A in the color image sensor.

The difference from the pixel array unit 11 illustrated in FIG. 4 above is that a filter layer 39 is formed between the planarization film 35 and the microlens 36. In order to indicate such a difference, the reference sign of the pixel in this case is “PxA”.

In the filter layer 39, a wavelength filter that transmits light in a predetermined wavelength band is formed for each pixel PxA. An example of the wavelength filter here can include a wavelength filter that transmits red (R) light, green (G) light, or blue (B) light.

Here, although not illustrated, in the pixel array unit 11A in the color image sensor, a plurality of unit color pixel groups in each of which a predetermined number of R pixels, G pixels, and B pixels are arranged in a predetermined pattern is arranged in the row direction and the column direction. For example, in the color image sensor adopting a Bayer array, 2×2=4 pixels PxA in which R, G, G, and B pixels PxA are arranged in a predetermined pattern are included in one unit color pixel group, and a plurality of the unit color pixel groups is arranged in the row direction and the column direction.

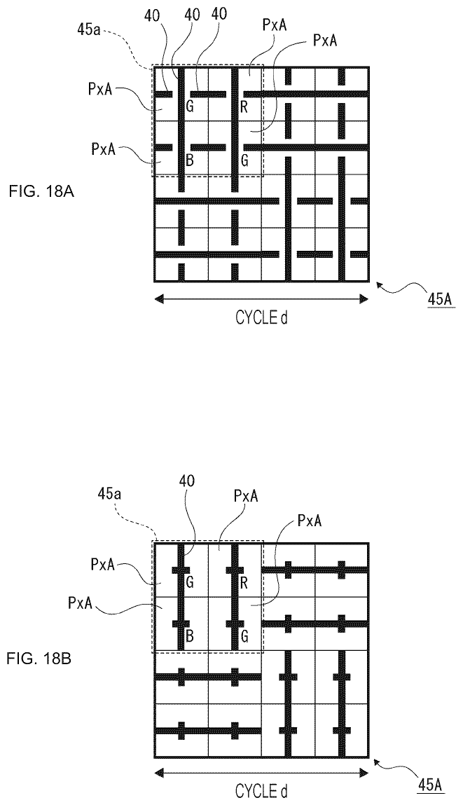

In the case of the color image sensor, as illustrated in the plan views of FIGS. 18A and 18B, it is conceivable to handle one unit color pixel group as one unit pixel 45a. That is, the pixel unit 45A in this case is formed by arranging a plurality of the unit pixels 45a as a unit color pixel group in the row direction and the column direction. Specifically, in the examples of FIGS. 18A and 18B, the pixel unit 45A includes 2×2=4 unit pixels 45a.

Also in this case, the formation patterns of the scattering structures 40 are the same in the unit pixel 45a. Then, in the pixel unit 45A, at least one unit pixel 45a is different from the other unit pixels 45a in the formation pattern of the scattering structure 40.

Specifically, in the examples of FIGS. 18A and 18B, similarly to the case of the first embodiment, a rotational symmetric shape of 2-fold symmetry is adopted as the planar shape of the scattering structure 40 in each pixel PxA, and in the pixel unit 45A, the unit pixels 45a are arranged with the rotation angles of the scattering structures 40 different by 90 degrees between the unit pixels 45a.

As a result, the periodicity of the scattering structure 40 can be disturbed in both the row direction and the column direction (also in this case, the cycle d can be the formation cycle of the pixel unit 45A), and the flare can be reduced. Also in this case, the formation patterns of the scattering structures 40 in each of the pixel units 45A can be the same, and thus the efficiency of a manufacturing process of the sensor device can be improved.

Note that, also in the second embodiment, the cycle d can be set so as to satisfy the condition of [Expression 3].

In addition, also in the second embodiment, the planar shape of the scattering structure 40 is not limited to a rotationally symmetric shape, and other shapes such as a chiral shape can be adopted.

### 3. Modification

Note that, an embodiment is not limited to the specific examples described above, and configurations as various modifications may be adopted.

For example, in the above description, regarding the distance measuring device 10 of the first embodiment, an example has been described in which the signal processing unit 17 that performs calculation for calculating a distance is provided in the sensor unit 1, but the signal processing unit 17 may be provided outside the sensor unit 1.

In addition, in the above description, an example has been described in which the present technology is applied to the infrared light receiving sensor and the color image sensor. However, the present technology can be also suitably applied to other sensor devices such as a polarization sensor and a thermal sensor, for example, as long as the sensor device is a sensor device in which a plurality of unit pixels that includes at least one pixel having a photoelectric conversion element and a scattering structure that scatters light incident on the photoelectric conversion element is arranged in the row direction and the column direction.

### 4. Summary of Embodiments

As described above, the sensor device (sensor unit 1) as an embodiment includes a plurality of pixel units (pixel units 45, 45A) arranged in a row direction and a column direction, in which each of the plurality of pixel units includes a plurality of unit pixels (unit pixels 45a) arranged in a row direction and a column direction, each of the plurality of unit pixels includes at least one pixel (pixel Px, PxA) having a photoelectric conversion element (photodiode PD) and a scattering structure (scattering structure 40) that scatters light incident on the photoelectric conversion element, and at least one of the unit pixels has a different formation pattern of the scattering structure from that of the other unit pixels.

Making the formation pattern of the scattering structure of some unit pixels different as described above enables the periodicity of the scattering structure to be disturbed. In addition, according to the above configuration, the formation patterns of the scattering structures can be the same in each of the pixel units.

Therefore, the flare can be reduced. In addition, the formation patterns of the scattering structures can be the same in each of the pixel units, and thus the efficiency of a manufacturing process of the sensor device can be improved.

In addition, in the sensor device as an embodiment, in each of the pixel units, there is a row in which the formation pattern of the scattering structures 40 in the row as a unit is different from that in the other rows, and there is a column in which the formation pattern of the scattering structures 40 in the column as a unit is different from that in the other columns.

With this configuration, the cycle of the scattering structure is prevented from becoming smaller than the cycle of the pixel unit in both the row direction and the column direction.

Accordingly, the flare reduction effect can be improved.

Furthermore, in the sensor device as an embodiment, the occurrence point of the flare due to at least the first-order diffracted light is located in the light receiving spot of the light source that is the occurrence source of the flare.

As a result, the flare due to at least the first-order diffracted light can be hidden in the light receiving spot of the light source that is the occurrence source of the flare, and deterioration in sensing accuracy due to the flare can be suppressed.

Furthermore, in the sensor device as an embodiment, when a formation cycle of the pixel unit is defined as d, a wavelength of light received on a light receiving surface is defined as 2, a diffraction angle of diffracted light according to a diffraction order=m generated on the light receiving surface is defined as 0, a distance between the light receiving surface and a reflecting surface of the diffracted light is defined as h, and a light receiving spot radius of the light source that is the occurrence source of the flare is defined as y, the above-described condition of [Expression 3] is satisfied.

Therefore, diffracted light of up to ±m-th order can be hidden in the light receiving spot of the light source.

As a result, deterioration in sensing accuracy due to the flare can be suppressed.

In addition, in the sensor device as an embodiment, the planar shapes and sizes of the scattering structures are the same in the respective pixels.

Therefore, the light receiving efficiency improving effects by the scattering structure can be equalized in the respective pixels.

As a result, it is possible to achieve both reduction of flare and reduction of the variation in the light receiving efficiency between the pixels.

Furthermore, in the sensor device as an embodiment, the planar shape of the scattering structure in each pixel is a rotationally symmetric shape, and in each of the pixel units, the scattering structure in at least one unit pixel is formed at a rotation angle different from that of the other unit pixels.

Therefore, in respective unit pixels, the periodicity of the scattering structure can be disturbed while the scattering structures have the same shape and the same size.

As a result, it is possible to achieve both reduction of flare and reduction of the variation in the light receiving efficiency between the pixels.

Furthermore, in the sensor device as an embodiment, in each of the pixel units, a scattering structure having chiral-shaped planar shapes between at least some unit pixels is formed.

Also in the case of adopting the chiral shape as the planar shape of the scattering structure, similarly to the case of having the same planar shape and the same size, the variation in the light receiving efficiency between the pixels can be reduced. In addition, by adopting the chiral shape, the periodicity of the scattering structure can be disturbed, and the flare also can be reduced.

In addition, the sensor device as an embodiment is an infrared light receiving sensor that receives infrared light.

The light receiving sensitivity of the photoelectric conversion element used at present to infrared light tends to be low.

Therefore, it is preferable to improve the light receiving efficiency by providing the scattering structure to increase the optical path length.

Furthermore, the sensor device as an embodiment is a ToF sensor that performs a light receiving operation for measuring a distance by a ToF method.

The ToF sensor performs the light receiving operation for infrared light, and is a type of the infrared light receiving sensor.

Therefore, it is preferable to improve the light receiving efficiency by providing the scattering structure to increase the optical path length.

Furthermore, the sensor device as an embodiment is a color image sensor that obtains a color image as a captured image.

As a result, in the color image sensor, it is possible to achieve both improvement of the light receiving efficiency by providing the scattering structure to increase the optical path length and reduction of the flare.

In addition, in the sensor device as an embodiment, a plurality of unit color pixel groups in which a predetermined number of R pixels, G pixels, and B pixels are arranged in a predetermined pattern is arranged in the row direction and the column direction, and each of the unit pixels includes the unit color pixel groups.

In this case, the pixel unit includes the plurality of unit color pixel groups arranged in the row direction and the column direction, and at least one unit color pixel group is formed to have a different formation pattern of the scattering structure from that of the other unit color pixel groups.

Therefore, in a sensor device in which a plurality of unit color pixel groups is arranged in the row direction and the column direction, for example, as a color image sensor adopting the Bayer array, it is possible to make the formation patterns of the scattering structures of some unit color pixel groups different, and it is possible to disturb the periodicity of the scattering structure and reduce flare. In addition, also in this case, the formation patterns of the scattering structures can be the same in each of the pixel units, and thus the efficiency of a manufacturing process of the sensor device can be improved.

Note that, the effects described in the present specification are merely examples and are not limited, and other effects may be exerted.

### 5. Present Technology

Note that, the present technology can also have the following configurations.

(1)

A sensor device including a plurality of pixel units arranged in a row direction and a column direction, in which each of the plurality of pixel units includes a plurality of unit pixels arranged in a row direction and a column direction, each of the plurality of unit pixels includes at least one pixel having a photoelectric conversion element and a scattering structure that scatters light incident on the photoelectric conversion element, and is, at least one of the unit pixels has a different formation pattern of the scattering structure from that of the other unit pixels.

(2)

The sensor device according to (1), in which in each of the pixel units, there is a row in which the formation pattern of the scattering structures in the row as a unit is different from that in the other rows, and there is a column in which the formation pattern of the scattering structures in the column as a unit is different from that in the other columns.

(3)

The sensor device according to (1) or (2), in which an occurrence point of flare due to at least first-order diffracted light is located in a light receiving spot of a light source that is an occurrence source of the flare.

(4)

The sensor device according to any one of (1) to (3), in which
when a formation cycle of the pixel units is defined as d, a wavelength of light received on a light receiving surface is defined as z, a diffraction angle of diffracted light of a diffraction order=m generated on a light receiving surface is defined as 8, a distance between a light receiving surface and a reflecting surface of the diffracted light is defined as h, and a light receiving spot radius of a light source that is an occurrence source of flare is defined as y,
a condition expressed as:

### [Math. 8]

is satisfied.
(5)

The sensor device according to any one of (1) to (4), in which
planar shapes and sizes of the scattering structures are the same in the respective pixels.
(6)

The sensor device according to (5), in which
a planar shape of the scattering structure in each of the pixels is a rotationally symmetric shape, and
in each of the pixel units, the scattering structure in at least one of the unit pixels is formed at a rotation angle different from that of the other unit pixels.
(7)

The sensor device according to (1) to (4), in which
in each of the pixel units, the scattering structure having chiral-shaped planar shapes between at least some of the unit pixels is formed.
   (8)

The sensor device according to any one of (1) to (7), in which
the sensor device is an infrared light receiving sensor that receives infrared light.
   (9)

The sensor device according to (8), in which
the sensor device is a ToF sensor that performs a light receiving operation for measuring a distance by a ToF method.
(10)

The sensor device according to any one of (1) to (7), in which
the sensor device is a color image sensor that obtains a color image as a captured image.
(11)

The sensor device according to (10), in which
a plurality of unit color pixel groups in which a predetermined number of R pixels, G pixels, and B pixels are arranged in a predetermined pattern is arranged in a row direction and a column direction, and
each of the unit pixels includes one of the unit color pixel groups.

### REFERENCE SIGNS LIST

1 Sensor unit (sensor device)
2 Light emitting unit
3 Control unit
4 Distance image processing unit
5 Memory
10 Distance measuring device
Ob Object
Li Irradiation light
Lr Reflected light
11 Pixel array unit
Px, PxA Pixel
PD Photodiode
31 Semiconductor substrate
32 Wiring layer
32a Wiring
32b Interlayer insulation film
33 Fixed charge film
34 Insulation film
35 Planarization film
36 Microlens
37 Inter-pixel separation unit
38 Inter-pixel light shielding unit
39 Filter layer
40 Scattering structure
45, 45A Pixel unit
45a Unit pixel

1. A sensor device comprising:
a plurality of pixel units arranged in a row direction and a column direction, wherein each of the plurality of pixel units includes a plurality of unit pixels arranged in a row direction and a column direction, each of the plurality of unit pixels includes at least one pixel having a photoelectric conversion element and a scattering structure that scatters light incident on the photoelectric conversion element, and at least one of the unit pixels has a different formation pattern of the scattering structure from that of the other unit pixels.

2. The sensor device according to claim 1, wherein
in each of the pixel units, there is a row in which the formation pattern of the scattering structures in the row as a unit is different from that in the other rows, and there is a column in which the formation pattern of the scattering structures in the column as a unit is different from that in the other columns.

3. The sensor device according to claim 1, wherein
an occurrence point of flare due to at least first-order diffracted light is located in a light receiving spot of a light source that is an occurrence source of the flare.

4. The sensor device according to claim 1, wherein
when a formation cycle of the pixel units is defined as d, a wavelength of light received on a light receiving surface is defined as λ, a diffraction angle of diffracted light of a diffraction order=m generated on a light receiving surface is defined as 0, a distance between a light receiving surface and a reflecting surface of the diffracted light is defined as h, and a light receiving spot radius of a light source that is an occurrence source of flare is defined as y,
a condition expressed as:
$$d ≧ \frac{m λ}{Sin \cdot {Tan}^{- 1} \cdot \frac{y}{2 h}} \qquad [ Math . 1 ]$$
is satisfied.

5. The sensor device according to claim 1, wherein
planar shapes and sizes of the scattering structures are the same in the respective pixels.

6. The sensor device according to claim 5, wherein
a planar shape of the scattering structure in each of the pixels is a rotationally symmetric shape, and
in each of the pixel units, the scattering structure in at least one of the unit pixels is formed at a rotation angle different from that of the other unit pixels.

7. The sensor device according to claim 1, wherein
in each of the pixel units, the scattering structure having chiral-shaped planar shapes between at least some of the unit pixels is formed.

8. The sensor device according to claim 1, wherein
the sensor device is an infrared light receiving sensor that receives infrared light.

9. The sensor device according to claim 8, wherein
the sensor device is a ToF sensor that performs a light receiving operation for measuring a distance by a ToF method.

10. The sensor device according to claim 1, wherein
the sensor device is a color image sensor that obtains a color image as a captured image.

11. The sensor device according to claim 10, wherein
a plurality of unit color pixel groups in which a predetermined number of R pixels, G pixels, and B pixels are arranged in a predetermined pattern is arranged in a row direction and a column direction, and
each of the unit pixel includes one of the unit color pixel groups.
